(19) United States
(12) Patent Application Publication
(10) Pub. No.: US 2003/0198301 A1
(43) Pub. Date: Oct. 23, 2003

(54) Method of epitaxial lateral overgrowth

(76) Inventors: Kazutaka Terashima, Hsinchu (TW); Mu-Jen Lai, Chuagli City (TW); Chiung-Yu Chang, Taichung (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/462,892

(22) Filed: Jun. 17, 2003

Related U.S. Application Data
(63) Continuation-in-part of application No. 10/062,116, filed on Jan. 30, 2002.

(30) Foreign Application Priority Data
Oct. 23, 2002 (TW) 91124482

(51) Int. Cl. H03K 9/00

(52) U.S. Cl. 375/316

(57) ABSTRACT

A method of epitaxial lateral overgrowth. First, a silicon substrate is provided. Next, a selective growth mask is formed on the substrate. The selective growth mask is patterned to form a plurality of opening windows between the adjacent patterned selective growth masks so as to expose the surface of the substrate thereon. Finally, a BP epitaxial layer is formed by vertically overgrowing the BP epitaxial layer on the surface of the substrate in the opening windows until the BP epitaxial layer is thicker than the patterned selective growth mask, and laterally overgrowing the BP epitaxial layer on the patterned selective growth mask.

### BACKGROUND OF THE INVENTION

1. Field of the Invention

The present invention relates to a light emitting device, and in particular to a method of epitaxial lateral overgrowth therefor.

2. Description of the Related Art

A group-III nitride semiconductor light-emitting diode is fabricated by providing an electrode on a stacked layer structure having a pn-junction type light-emitting part comprising, for example, aluminum gallium indium nitride (AlₓGa_{y}In_{1-x-y}N, where 0≦X, Y≦1 and 0≦X+Y≦1). In the stacked layer structure, a buffer layer is generally provided for relaxing lattice mismatch between the substrate material and the group-III nitride semiconductor layer constituting the stacked layer structure, thereby growing a high-quality group-III nitride semiconductor layer. Conventionally, for example, in the stacked layer structure for use in a light-emitting device using a sapphire (α-Al₂O₃ single crystal) substrate, the buffer layer is exclusively composed of aluminum gallium nitride (compositional formula; Al_{α}Ga_{β}N, where 0≦α, β≦1).

However, the cost of the conventional sapphire substrate is prohibitive. As well, the performance of the light-emitting device depends on the quality of the structure of the stacked layers, such that formation of stacked layers with precise structure is important.

### SUMMARY OF THE INVENTION

Accordingly, an object of the present invention is to provide a method of epitaxial lateral overgrowth to reduce defects therefrom and produce a precise crystalline structure.

It is a further object of the present invention to provide a method of epitaxial lateral overgrowth for a light-emitting device to enhance lighting efficiency and prolong lifetime.

It is still another object of the present invention to provide a method of epitaxial lateral overgrowth for a light-emitting device using a silicon substrate to save material costs using a BP buffer layer to reduce lattice mismatch between the silicon substrate and the GaN cladding layer.

One of the key features of the present invention is use of the BP buffer layer to reduce the lattice mismatch between the silicon substrate and the GaN cladding layer.

Another key feature of the present invention is use of selective growth mask, such that the epitaxial layer can grow vertically in the opening windows between the selective growth masks at the beginning. After the epitaxial layer is thicker than the selective growth mask, the epitaxial layer grows laterally, gradually extending over the selective growth mask. The crystalline structure of the epitaxial layer growing laterally is precise, with few dislocations therein, a favorable choice for manufacturing a light-emitting device.

To achieve these and other advantages, the invention provides a method of epitaxial lateral overgrowth. First, a silicon substrate is provided. Next, a selective growth mask is formed on the substrate. The selective growth mask is patterned to form a plurality of opening windows between the adjacent patterned selective growth masks so as to expose the surface of the substrate thereon. Finally, a BP epitaxial layer is formed by vertically overgrowing the BP epitaxial layer on the surface of the substrate in the opening windows until the BP epitaxial layer is thicker than the patterned selective growth mask and laterally overgrows the BP epitaxial layer on the patterned selective growth mask.

The invention also provides a method of epitaxial lateral overgrowth for forming a cladding layer. First, a silicon substrate is provided. Next, a BP buffer layer is formed on the silicon substrate. A selective growth mask is formed on the BP buffer layer. The selective growth mask is patterned to form a plurality of opening windows between the patterned selective growth masks so as to expose the surface of the BP buffer layer thereon. Finally, a cladding layer is formed by vertically overgrowing the cladding layer on the surface of the BP buffer layer in the opening windows until the cladding layer is thicker than the patterned selective growth mask and laterally overgrowing the cladding layer on the patterned selective growth mask.

The cladding layer is a gallium nitride based compound semiconductor comprising AlₓIn₁₋ₓGa_{y}N_{1-y}(0<x<1, 0<y<1) or AlₓGa₁₋ₓN_{y}P_{1-y} (0<x<1, 0<y<1). The precursors of the gallium nitride based compound semiconductor formation comprise monomethyl hydrazine (MMH) and trimethyl gallium (TMG).

The cladding layer overgrows vertically at about 350˜500° C., and the cladding layer overgrows laterally at about 780˜850° C.

The invention further provides a method of epitaxial lateral overgrowth for forming an active layer. First, a silicon substrate is provided. Next, a BP buffer layer is formed on the silicon substrate. A GaN cladding layer is formed on the BP buffer layer. A selective growth mask is formed on the GaN cladding layer. The selective growth mask is patterned to form a plurality of opening windows between the patterned selective growth masks so as to expose the surface of the GaN cladding layer thereon. Finally, an active layer is formed by vertically overgrowing the cladding layer on the surface of the CaN cladding layer in the opening windows until the active layer is thicker than the patterned selective growth mask and laterally overgrowing the active layer on the patterned selective growth mask.

The active layer comprises In_{y}GaN (0<y<1)

According to the present invention, the selective growth mask comprising SiO₂ can be patterned using a HF solution as an etching agent, and the thickness of the selective growth mask is about 1500 Å˜15000 Å.

The precursors of the BP formation comprise a combination of BCl₃ and PCl₃ or a combination of BCl₃ and PH₃. As well, hydrogen gas is preferably introduced as a carrier gas during formation of the BP epitaxial layer.

### BRIEF DESCRIPTION OF THE DRAWINGS

The present invention can be more fully understood by reading the subsequent detailed description and examples with references made to the accompanying drawings, wherein:

FIGS. 1A through 1E are cross-sections showing the method according to a preferred embodiment of the present invention;

FIGS. 2A through 2E are cross-sections showing the method according to another preferred embodiment of the present invention; and

FIGS. 3A through 3E are cross-sections showing the method according to still another preferred embodiment of the present invention.

### DETAILED DESCRIPTION OF THE INVENTION

First embodiment

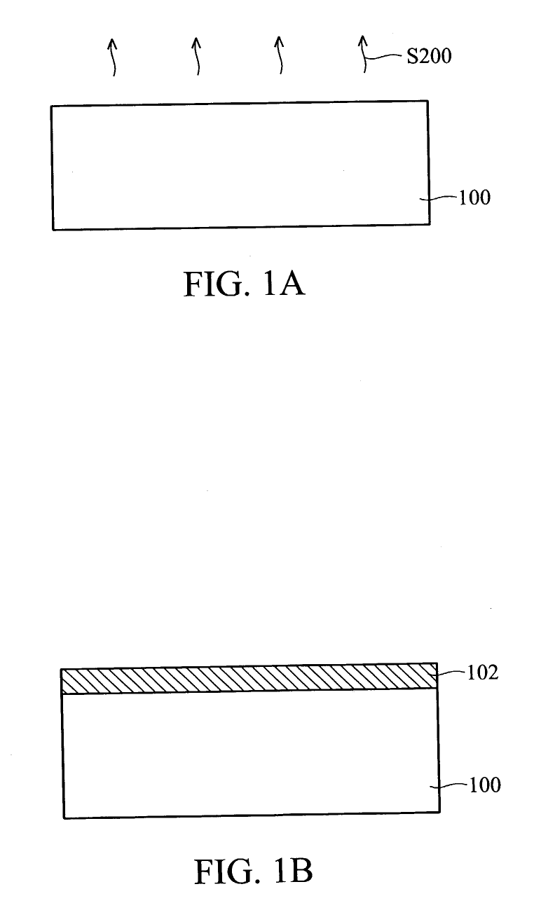

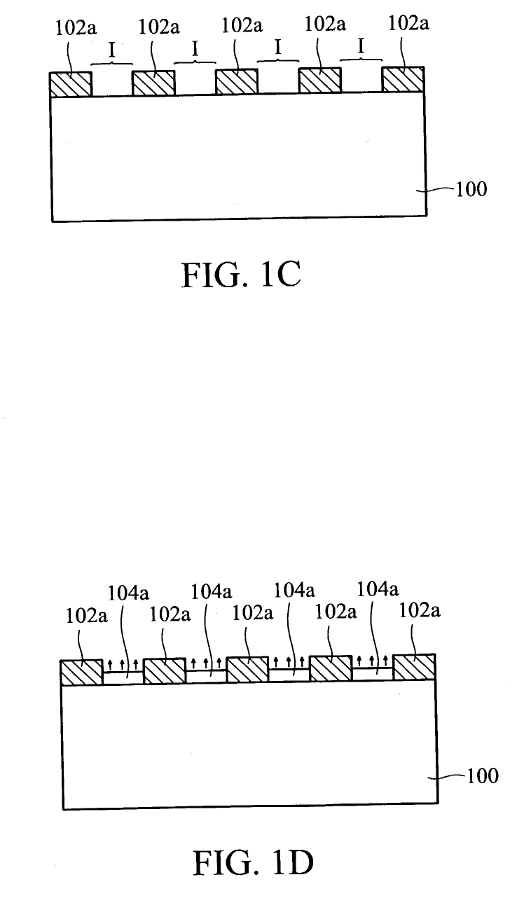

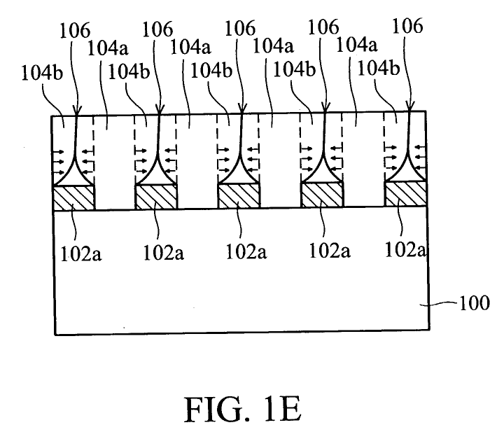

An embodiment of the present invention is now described with reference to FIG. 1A through FIG. 1E illustrating a BP layer laterally overgrowing on a silicon substrate.

First, in FIG. 1A, a substrate 100 is provided. Next, a selective growth mask 102 comprising SiO₂ is preferably formed on {100} planes of the substrate 100 by thermal oxidizing S200 at about 1000° C., as shown in FIG. 1B. The thickness of the selective growth mask 102 is about 1500 Å˜15000 Å.

In FIG. 1C, the selective growth mask 102 is preferably patterned by a HF solution to remove parts of the selective growth mask 102 so as to form a plurality of opening windows I between the adjacent patterned selective growth masks 102a. Thus, opening windows I with a certain area are obtained, and the surface of the substrate 100 is exposed thereby. Each of the opening windows I is about 50 μm×4000 μm.

In FIG. 1D, a BP layer 104a is formed by epitaxy. The BP epitaxial layer 104a vertically overgrows the surface of the substrate 100 in the opening windows I until the BP epitaxial layer 104a is thicker than the patterned selective growth mask 102a.

Finally, the BP epitaxial layer 104a is laterally overgrown, as shown in FIG. 1E. The BP epitaxial lateral layers 104b growing from the adjacent opening windows and extending gradually over the patterned selective growth mask 102a combine into one, such that a crack 106 is formed above the patterned selective growth mask 102a.

The preferred embodiment of forming the BP layer 104a, 104b is described herein.

First, the temperature of the reactive chamber housing the substrate 100 with the patterned selective growth mask 102a is brought to about 900˜1180° C. for one minute. Next, after the temperature of the reactive chamber is lowered to about 380° C., PCl₃ or PH₃ is introduced. Three minutes later, BCl₃ is introduced into the chamber for 40 minutes, and the temperature of the chamber is maintained at about 380° C. for 5 min. Then, the temperature of the chamber is brought to about 1030° C., and BCl₃ is introduced into the chamber again for 60 minutes. PCl₃ or PH₃ is continually supplied. Finally, the reactive gas comprising PCl₃ or PH₃ and BCl₃ has its supply terminated, and the temperature of the chamber is maintained at about 1030° C. for 10 min. The BP layer 104a, 104b is formed on the substrate 100 and the patterned selective growth mask 102a. After decreasing the temperature of the chamber to room temperature, the BP layer 104a, 104b is formed. Throughout the entire process, hydrogen is continually introduced into the chamber.

The BP layer 104a formed in the opening window having high density of dislocations is not good for a light-emitting device. However, the crystal structure of the BP layer 104b formed on the selective growth mask 102a is precise enough that lighting efficiency is enhanced and lifetime is prolonged, such that it can serve as a buffer layer to reduce lattice mismatch. Along the crack 106, the BP lateral overgrowing layer 104b is preferably split for a light-emitting device.

Second Embodiment

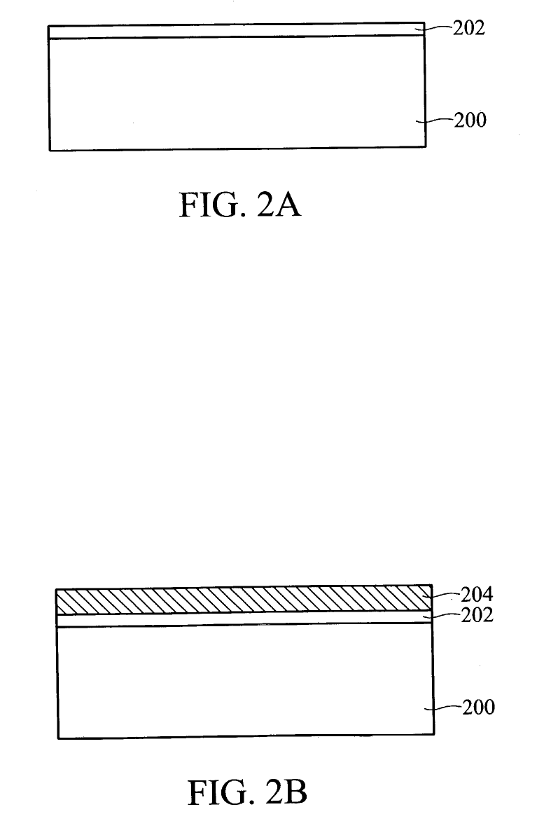

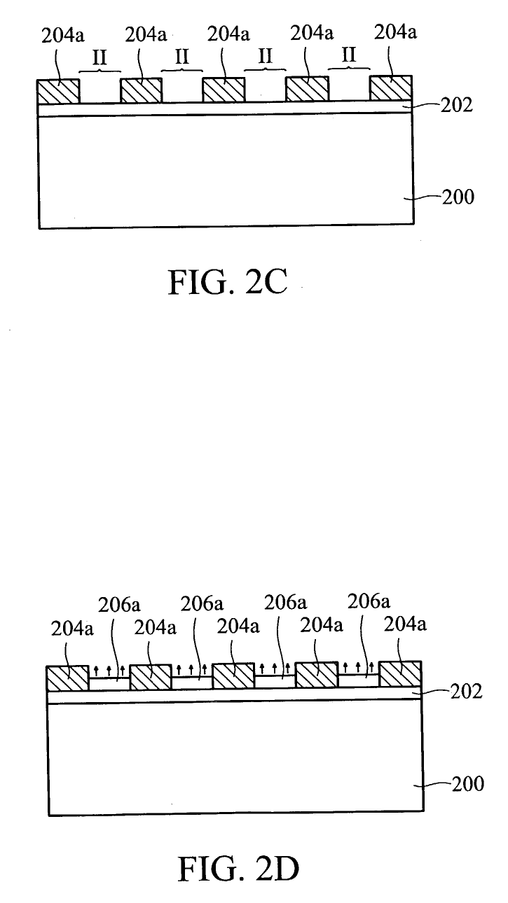

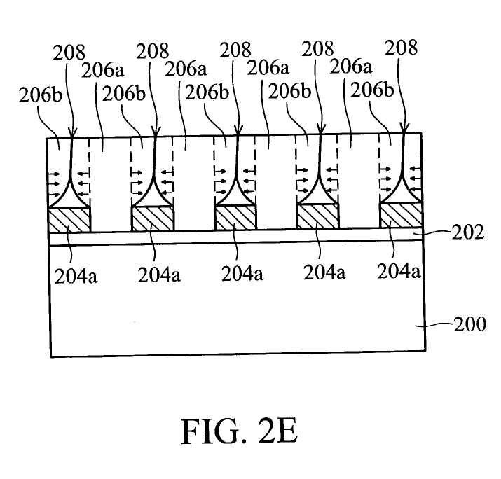

An embodiment of the present invention is now described with reference to FIG. 2A through FIG. 2E illustrating a cladding layer laterally overgrowing on a BP buffer layer.

First, in FIG. 2A, a substrate 200 is provided.

Next, a BP buffer layer 202 is preferably formed on {100} planes of the silicon substrate 200. BP formation is consistent with the description outlined in the previous embodiment.

A selective growth mask 204 comprising SiO₂ is preferably formed on BP buffer layer 202 by chemical vapor deposition (CVD), as shown in FIG. 2B. The thickness of the selective growth mask 204 is about 1500 Å˜15000 Å.

In FIG. 2C, the selective growth mask 204 is preferably patterned by HF solution to remove parts of the selective growth mask 204 so as to form a plurality of opening windows II between the adjacent patterned selective growth masks 204a. Thus, the opening windows II with a certain area are obtained, and the surface of the BP buffer layer 202 is exposed thereby. Each of the opening windows II is about 50 μm×4000 μm.

In FIG. 2D, a cladding layer 206a is formed by epitaxy. The cladding layer 206a vertically overgrows the surface of the BP buffer layer 202 in the opening windows II at about 350˜500° C. until the cladding layer 206a is thicker than the patterned selective growth mask 204a.

Finally, the cladding layer 206a is laterally overgrown at about 780˜850° C., as shown in FIG. 2E. The cladding lateral layer 206b growing from the adjacent opening windows II and extending gradually over the patterned selective growth -mask 204a combine into one, such that a crack 208 is formed above the patterned selective growth mask 204a.

The cladding layer 206a, 206b is a gallium nitride based compound semiconductor comprising AlₓIn₁₋ₓGa_{y}N_{1-y} (0<x<1, 0<y<1) or AlₓGa₁₋ₓN_{y}P_{1-y} (0<x<1, 0<y<1), such as GaN, InGaN, AlGaN, and GaNP. The precursors of the gallium nitride based compound semiconductor formation comprise monomethyl hydrazine (MMH) and trimethyl gallium (TMG).

A preferred embodiment of GaN cladding layer formation is described herein as an example.

First, hydrogen, nitrogen and MMH are introduced into the chamber housing the substrate 200 having the buffer layer 202 and the patterned selective growth mask 204a at about 350˜500° C. After 3 minutes, TMG is introduced into the chamber for about 20 minutes. 5 minutes later, the temperature of the chamber is brought to about 820° C. TMG is introduced into the chamber again for 60 min at about 820° C. Throughout the entire process, MMH is continuously introduced. Finally, the temperature of the chamber is maintained at about 820° C. for 30 minutes after stopping to introduce MMH and TMG. After decreasing the temperature of the chamber to room temperature, the process of forming the GaN semiconductor layer 206a, 206b is accomplished.

The cladding layer 206a formed in the opening window II having high density of dislocations is not good for a light-emitting device. However, the crystal structure of the cladding layer 206b formed on the selective growth mask 204a is precise enough that lighting efficiency is enhanced and lifetime is prolonged. As well, the BP buffer layer 202 can reduce lattice mismatch between the substrate 200 and the cladding layer 206a, 206b. Along the crack 208, the cladding lateral overgrowing layer 206b is preferably split for a light-emitting device.

Third Embodiment

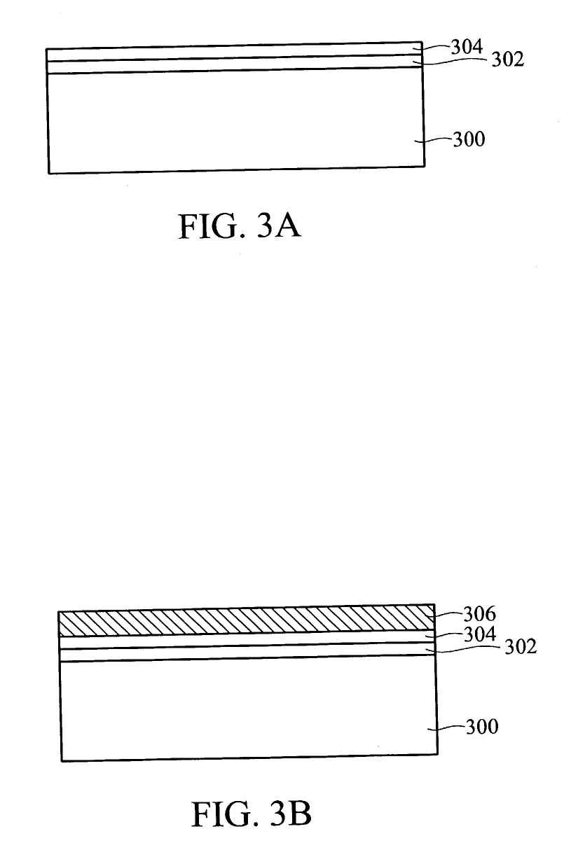

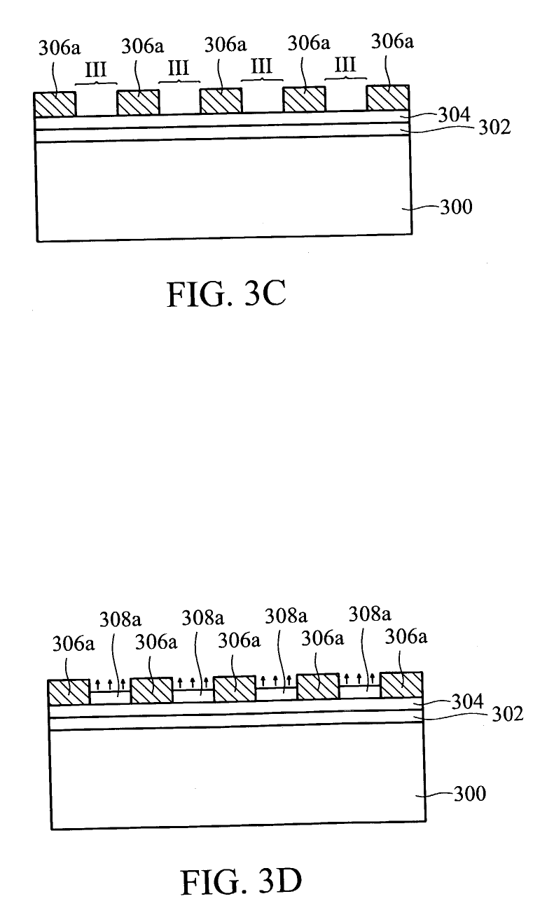

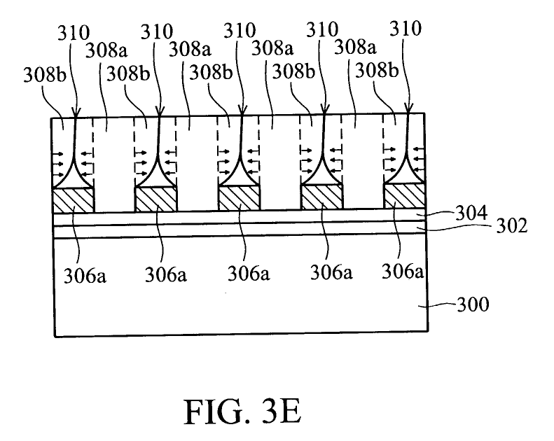

An embodiment of the present invention is now described with reference to FIG. 3A through FIG. 3E illustrating an active layer laterally overgrowing on a cladding layer.

First, in FIG. 3A, a substrate 300 is provided.

Next, a BP buffer layer 302 is preferably formed on {100} planes of the silicon substrate 300. BP formation is consistent with the description outlined in the previous embodiment. A cladding layer 304 comprising GaN is formed on the BP buffer layer 302.

The cladding layer 304 is a gallium nitride based compound semiconductor comprising AlₓIn₁₋ₓGa_{y}N_{1-y} (0<x<1, 0<y<1) or AlₓGa₁₋ₓN_{y}P_{1-y} (0<x<1, 0<y<1), such as GaN, InGaN, AlGaN, and GaNP. The precursors of the gallium nitride based compound semiconductor formation comprise monomethyl hydrazine (MMH) and trimethyl gallium (TMG).

GaN formation is consistent with the description outlined in the previous embodiment.

In FIG. 3B, a selective growth mask 306 comprising SiO₂ is preferably formed on cladding layer 304 by chemical vapor deposition (CVD). The thickness of the selective growth mask 306 is about 1500 Å˜15000 Å.

In FIG. 3C, the selective growth mask 306 is preferably patterned by HF solution to remove parts of the selective growth mask 306 so as to form a plurality of opening windows III between the adjacent patterned selective growth masks 306a. Thus, opening windows III with a certain area are obtained, and the surface of the cladding layer 304 is exposed thereby. Each of the opening windows III is about 50 μm x 4000 μm.

In FIG. 3D, an active layer 308a is formed by epitaxy. The active layer 308a vertically overgrows the surface of the cladding layer 304 in the opening windows III at about 350˜500° C. until the active layer 308a is thicker than the patterned selective growth mask 306a.

Finally, the active layer 308a is laterally overgrown at about 780˜850° C., as shown in FIG. 3E. The active lateral layer 308a growing from the adjacent opening windows III and extending gradually over the patterned selective growth mask 306a combine into one, such that a crack 310 is formed above the patterned selective growth mask 306a.

The active layer comprises In_{y}GaN (0<y<1) The active layer 308a formed in the opening window III having high density of dislocations is not good for a light-emitting device. However, the crystal structure of the active layer 308b formed on the selective growth mask 306a is precise enough that lighting efficiency is enhanced and lifetime is prolonged. As well, the BP buffer layer 302 can reduce lattice mismatch between the silicon substrate 300 and the cladding layer 304. Along the crack 310, the active lateral overgrowing layer 2308b is preferably split for a light-emitting device.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of epitaxial lateral overgrowth, comprising:
providing a silicon substrate;
forming a selective growth mask on the substrate;
patterning the selective growth mask to form a plurality of opening windows between the adjacent patterned selective growth masks so as to expose the surface of the substrate thereon; and
forming a BP epitaxial layer, comprising:
vertically overgrowing the BP epitaxial layer on the surface of the substrate in the opening windows until the BP epitaxial layer is thicker than the patterned selective growth mask; and
laterally overgrowing the BP epitaxial layer on the patterned selective growth mask.

2. The method as claimed in claim 1, wherein the selective growth mask comprises SiO₂.

3. The method as claimed in claim 1, wherein the thickness of the selective growth mask is about 1500 Å˜15000 Å.

4. The method as claimed in claim 1, wherein the precursors of the BP formation comprise a combination of BCl₃ and PCl₃ or a combination of BCl₃ and PH₃.

5. The method as claimed in claim 1, wherein hydrogen gas is introduced as a carrier gas during formation of the BP epitaxial layer.

6. The method as claimed in claim 2, wherein the selective growth mask is patterned using a HF solution as an etching agent.

7. A method of epitaxial lateral overgrowth, comprising:
providing a silicon substrate;
forming a BP buffer layer on the silicon substrate;
forming a selective growth mask on the BP buffer layer;
patterning the selective growth mask to form a plurality of opening windows between the adjacent patterned selective growth masks so as to expose the surface of the BP buffer layer thereon; and
forming a cladding layer, comprising:
vertically overgrowing the cladding layer on the surface of the BP buffer layer in the opening windows until the cladding layer is thicker than the patterned selective growth mask; and
laterally overgrowing the cladding layer on the patterned selective growth mask.

8. The method as claimed in claim 7, wherein the selective growth mask comprises SiO₂.

9. The method as claimed in claim 7, wherein the thickness of the selective growth mask is about 1500 Å˜15000 Å.

10. The method as claimed in claim 7, wherein the BP buffer layer is formed by halide vapor phase epitaxy using a combination of BCl₃ and PCl₃ or a combination of BCl₃ and PH₃ as precursors.

11. The method as claimed in claim 7, wherein the cladding layer is a gallium nitride based compound semiconductor comprising AlₓIn₁₋ₓGa_{y}N_{1-y} (0<x<1, 0<y<1) or AlₓGa₁₋ₓN_{y}p_{1-y} (0<x<1, 0<y<1).

12. The method as claimed in claim 11, wherein the precursors of the gallium nitride based compound semiconductor formation comprise monomethyl hydrazine (MMH) and trimethyl gallium (TMG).

13. The method as claimed in claim 11, wherein the cladding layer overgrows vertically at about 350˜500° C.

14. The method as claimed in claim 11, wherein the cladding layer overgrows laterally at about 780˜850° C.

15. A method of epitaxial lateral overgrowth, comprising:
providing a silicon substrate;
forming a BP buffer layer on the silicon substrate;
forming a GaN cladding layer on the BP buffer layer;
forming a selective growth mask on the GaN cladding layer;
patterning the selective growth mask to form a plurality of opening windows between the adjacent patterned selective growth masks so as to expose the surface of the GaN cladding layer thereon; and
forming an active layer, comprising:
vertically overgrowing the cladding layer on the surface of the GaN cladding layer in the opening windows until the active layer is thicker than the patterned selective growth mask; and
laterally overgrowing the active layer on the patterned selective growth mask.

16. The method as claimed in claim 15, wherein the selective growth mask comprises SiO₂.

17. The method as claimed in claim 15, wherein the thickness of the selective growth mask is about 1500 Å˜15000 Å.

18. The method as claimed in claim 15, wherein the BP buffer layer is formed by halide vapor phase epitaxy using a combination of BCl₃ and PCl₃ or a combination of BCl₃ and PH₃ as precursors.

19. The method as claimed in claim 15, wherein the GaN cladding layer is formed by metal organic vapor phase epitaxy (MOVPE) using monomethyl hydrazine (MMH) and trimethyl gallium (TMG) as precursors.

20. The method as claimed in claim 15, wherein the active layer comprises In_{y}GaN (0y<1).
